(19) United States
(12) Patent Application Publication
(10) Pub. No.: US 2024/0128014 A1
(43) Pub. Date: Apr. 18, 2024

(54) INDUCTOR COMPONENT

(71) Applicant: Murata Manufacturing Co., Ltd., Kyoto-fu (JP)

(72) Inventor: Keisuke KUNIMORI, Nagaokakyo-shi (JP)

(73) Assignee: Murata Manufacturing Co., Ltd., Kyoto-fu (JP)

(21) Appl. No.: 18/479,889

(22) Filed: Oct. 3, 2023

(30) Foreign Application Priority Data
Oct. 14, 2022 (JP) 2022-165735

(51) Int. Cl. H01F 27/32; H01F 27/28

(52) U.S. Cl. CPC H01F 27/323; H01F 27/2823

(57) ABSTRACT

An inductor component includes first and second internal wiring lines, an interlayer insulating layer between the first and second internal wiring lines and having a first main surface facing the first internal wiring line, a second main surface facing the second internal wiring line, and a via extending between the first main surface and the second main surface, and a via wiring line inserted through the via that electrically connects the first and second internal wiring lines. In a first section including a central axis of the via wiring line, the first main surface includes a first portion in contact with the first internal wiring line. The second main surface includes a second portion that is parallel to the first portion. A straight line that includes the first portion is a first reference line. A straight line that includes the second portion is a second reference line.

### CROSS-REFERENCE TO RELATED APPLICATION

This application claims benefit of priority to Japanese Patent Application No. 2022-165735, filed Oct. 14, 2022, the entire content of which is incorporated herein by reference.

### BACKGROUND

### Technical Field

The present disclosure relates to an inductor component.

### Background Art

Japanese Unexamined Patent Application Publication No. 2020-107877 describes an example of an electronic component. In the related art, an electronic component includes, for example, two internal wiring lines, an insulating layer that is disposed between the two internal wiring lines and that has a via, and a via wiring line that is inserted through the via. The via wiring line electrically connects the two internal wiring lines to each other. The via has a tapered shape such that its diameter decreases in a depth direction.

### SUMMARY

However, in an electronic component of the related art, the shear strength between a via wiring line and an internal wiring line is not sufficient, and connection reliability may sometimes decrease.

Accordingly, the present disclosure provides an inductor component having high shear strength between a via wiring line and an internal wiring line.

An inductor component according to an aspect of the present disclosure includes a first internal wiring line, a second internal wiring line, an interlayer insulating layer that is disposed between the first internal wiring line and the second internal wiring line and that has a first main surface facing the first internal wiring line, a second main surface facing the second internal wiring line, and a via extending between the first main surface and the second main surface, and a via wiring line that is inserted through the via and that electrically connects the first internal wiring line and the second internal wiring line to each other. In a first section including a central axis of the via wiring line, the first main surface includes a first portion that is in contact with the first internal wiring line. The second main surface includes a second portion that is parallel to the first portion. A straight line that includes the first portion is defined as a first reference line. A straight line that includes the second portion is defined as a second reference line. The interlayer insulating layer includes a protrusion that is in contact with the second internal wiring line and that is located between the second reference line and the second internal wiring line.

According to the above-described aspect, the shear strength between the via wiring line and each of the internal wiring lines can be increased.

With an inductor component according to an aspect of the present disclosure, the shear strength between a via wiring line and each internal wiring line is increased.

### BRIEF DESCRIPTION OF THE DRAWINGS

FIG. 1 is a plan view illustrating an inductor component according to a first embodiment in a see-through manner;

FIG. 2 is a sectional view taken along line II-II of FIG. 1;

FIG. 3A is an enlarged view of a portion A illustrated in FIG. 2;

FIG. 3B is an enlarged view of a portion B illustrated in FIG. 3A;

FIG. 3C is an enlarged view of a portion C illustrated in FIG. 3A;

FIG. 4A is a schematic sectional view illustrating a method of manufacturing the inductor component;

FIG. 4B is a schematic sectional view illustrating the method of manufacturing the inductor component;

FIG. 4C is a schematic sectional view illustrating the method of manufacturing the inductor component;

FIG. 4D is a schematic sectional view illustrating the method of manufacturing the inductor component;

FIG. 4E is a schematic sectional view illustrating the method of manufacturing the inductor component;

FIG. 4F is a schematic sectional view illustrating the method of manufacturing the inductor component;

FIG. 4G is a schematic sectional view illustrating the method of manufacturing the inductor component;

FIG. 4H is a schematic sectional view illustrating the method of manufacturing the inductor component;

FIG. 4I is a schematic sectional view illustrating the method of manufacturing the inductor component;

FIG. 4J is a schematic sectional view illustrating the method of manufacturing the inductor component;

FIG. 4K is a schematic sectional view illustrating the method of manufacturing the inductor component; and

FIG. 4L is a schematic sectional view illustrating the method of manufacturing the inductor component.

### DETAILED DESCRIPTION

An inductor component according to an embodiment of the present disclosure will be described in detail below with reference to the drawings. Note that some of the drawings schematically illustrate objects, and the dimensional ratios of the objects illustrated in the drawings may sometimes be different from those of the actual objects.

(Configuration)

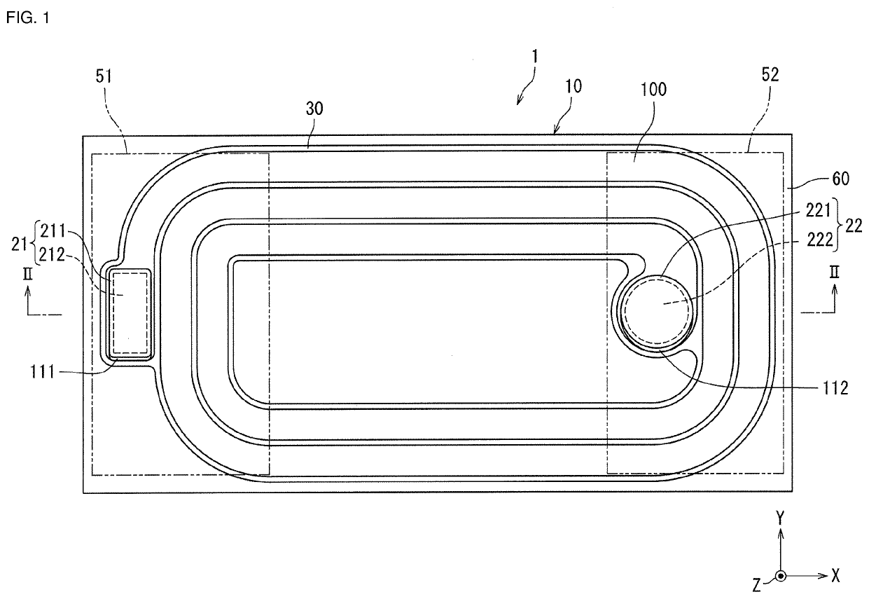

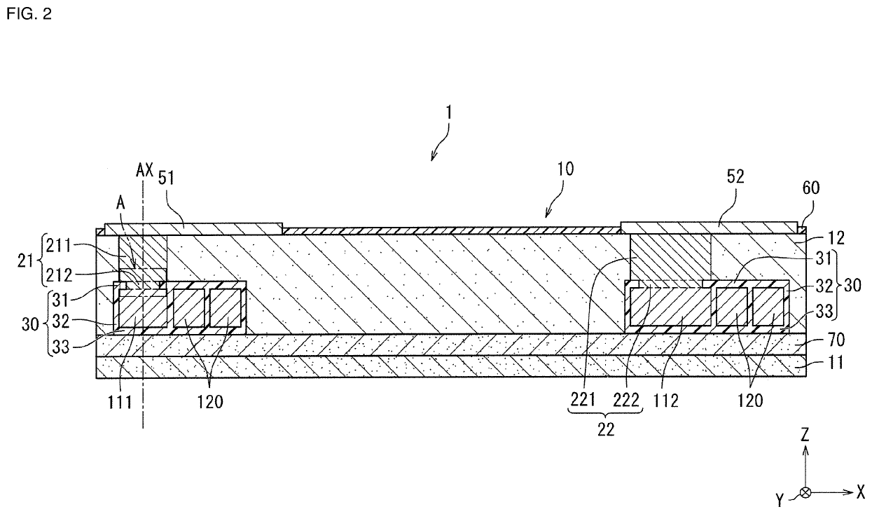

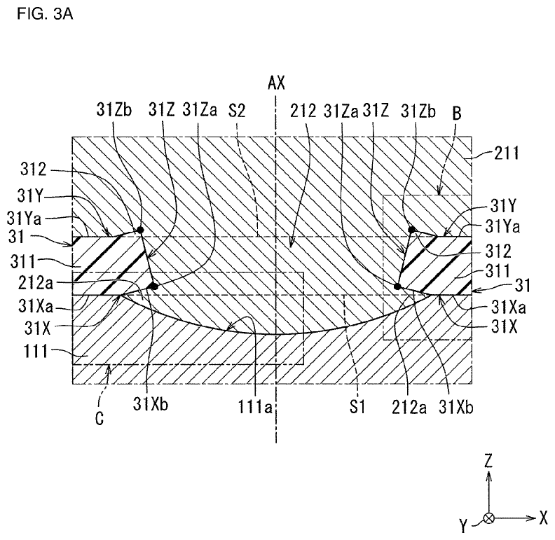

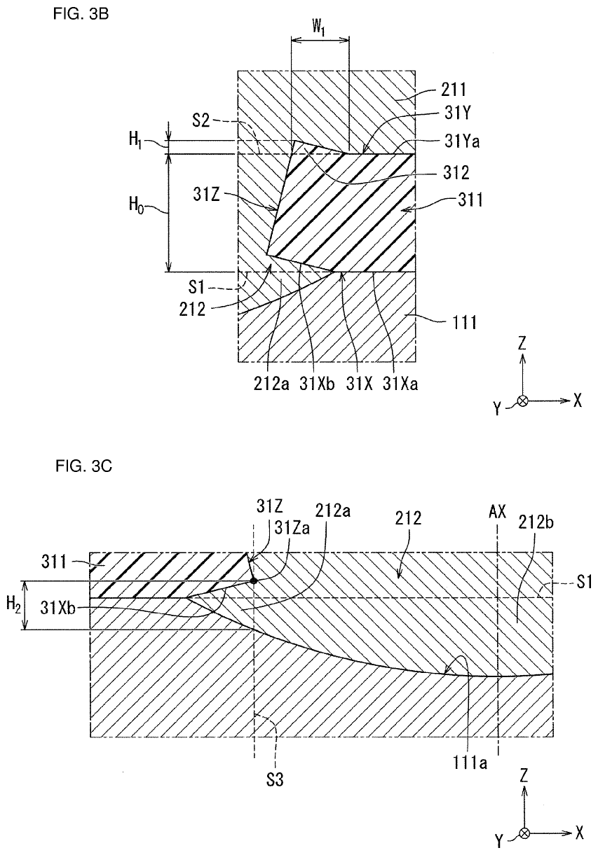

FIG. 1 is a plan view illustrating the inductor component according to the embodiment in a see-through manner. FIG. 2 is a sectional view taken along line II-II of FIG. 1. FIG. 2 illustrates an XZ section including a central axis AX of a via wiring line. The XZ section is an example of a first section including the central axis AX. For convenience of description, FIG. 2 does not illustrate a protrusion of an interlayer insulating layer, which will be described later, a constricted portion of a via wiring line, a projection of the via wiring line, a recess of a first pad portion, and a seed layer. These are illustrated in FIG. 3A and the subsequent drawings.

In the drawings, a thickness direction of an inductor component 1 will be referred to as a Z direction. In a plane of the inductor component 1 that is perpendicular to the Z direction, a length direction that is the longitudinal direction of the inductor component 1 and a direction in which a first external terminal 51 and a second external terminal 52 are arranged will be referred to as an X direction. A width direction of the inductor component 1, which is a direction perpendicular to the length direction, will be referred to as a Y direction. The XZ sectional view is obtained by cutting the inductor component 1 along a plane that is formed of a straight line extending in the X direction and a straight line extending in the Z direction and that includes the central axis AX of the via wiring line.

For example, the inductor component 1 is installed in an electronic device, such as a personal computer, a digital versatile disc (DVD) player, a digital camera, a television set (TV), a cellular phone, automotive electronics, and is a component that has, for example, a rectangular parallelepiped shape when seen as a whole. However, the shape of the inductor component 1 is not particularly limited and may be a columnar shape, a polygonal columnar shape, a truncated conical shape, or a polygonal truncated pyramidal shape.

As illustrated in FIG. 1 and FIG. 2, the inductor component 1 includes an element body 10, an inductor wiring line 100, an insulating layer 30, a first vertical wiring line 21, a second vertical wiring line 22, a first external terminal 51, and a second external terminal 52. Note that, in FIG. 1, the external terminals are each indicated by a two-dot chain line for convenience of description. In addition, in FIG. 1, although the element body 10 and a coating film 60 are illustrated as being transparent for ease of understanding of the structure, they may be translucent or opaque.

The element body 10 includes a first magnetic layer 11, a substrate 70 that is disposed on the first magnetic layer 11, and a second magnetic layer 12 that is disposed on the substrate 70. The first magnetic layer 11, the substrate 70, and the second magnetic layer 12 are laminated together such that the inductor wiring line 100 and the insulating layer 30 are sandwiched therebetween in a direction in which the central axis AX of a first via wiring line 212 extends. In other words, the inductor wiring line 100 and the insulating layer 30 are arranged in the element body 10. Although the element body 10 has a three-layered structure formed of the first magnetic layer 11, the substrate 70, and the second magnetic layer 12, the element body 10 may have a two-layered structure formed of the first magnetic layer 11 and the second magnetic layer 12.

In the following direction, an upward direction corresponds to the direction in which the central axis AX of the first via wiring line 212 extends (or the Z direction), that is, the direction from the first magnetic layer 11 toward the second magnetic layer 12. An upper surface of an element refers to a surface of the element that faces in the upward direction. A downward direction corresponds to the direction in which the central axis AX of the first via wiring line 212 extends, that is the direction from the second magnetic layer 12 toward the first magnetic layer 11. A lower surface of an element refers to a surface of the element that faces in the downward direction.

The width direction corresponds to direction perpendicular to the direction in which the central axis AX of the first via wiring line 212 extends and is also referred to as the Y direction as mentioned above. The width of an element refers to the length of the element in the width direction. A thickness direction corresponds to a direction parallel to the direction in which the central axis AX of the first via wiring line 212 extends and is also referred to as the Z direction as mentioned above. The thickness of an element refers to the length of the element in the thickness direction.

An inductor wiring line has a curve (a two-dimensional curve) extending on a plane, and the curve may have more than one turn or may have less than one turn. Alternatively, a portion of an inductor wiring line may have a straight line.

The first magnetic layer 11 and the second magnetic layer 12 each contains a resin and a metal magnetic powder that is included in the resin and that serves as a magnetic material. Thus, compared with a magnetic layer that is made of ferrite, the direct-current superposition characteristics can be improved due to the metal magnetic powder, and particles of the metal magnetic powder are insulated from each other by the resin, so that a loss (an iron loss) at a high frequency can be reduced.

The resin includes, for example, any of an epoxy-based resin, a polyimide-based resin, a phenol-based resin, and a vinyl ether-based resin. As a result, the electrical insulation reliability is improved. More specifically, the resin is an epoxy resin, a mixture of an epoxy resin and an acrylic resin, or a mixture of an epoxy resin, an acrylic resin, and another resin. This ensures the electrical insulation between the particles of the metal magnetic powder, and thus, a loss (an iron loss) at a high frequency can be reduced.

The average particle diameter of the metal magnetic powder is, for example, 0.1 μm or more and 5 μm or less (i.e., from 0.1 μm to 5 μm). During a process of manufacturing the inductor component 1, the average particle diameter of the metal magnetic powder can be calculated as a particle diameter equivalent to 50% of an integrated value in a particle-diameter distribution obtained by a laser diffraction/scattering method. The metal magnetic powder is, for example, an FeSi-based alloy such as FeSiCr, a FeCo-based alloy, an Fe-based alloy such as NiFe, or an amorphous alloy of any of these. The metal magnetic powder content of the entire magnetic layer is preferably 20 vol % or more 70 vol % or less (i.e., from 20 vol % to 70 vol %). In the case where the average particle diameter of the metal magnetic powder is 5 μm or less, the direct-current superposition characteristics are further improved, and since the metal magnetic powder is fine powder, an iron loss at a high frequency can be reduced. In the case where the average particle diameter of the metal magnetic powder is 0.1 μm or more, it is easy to evenly disperse the metal magnetic powder in the resin, and the efficiency of manufacturing the first magnetic layer 11 and the second magnetic layer 12 is improved. Note that, instead of the metal magnetic powder or in addition to the metal magnetic powder, a ferrite magnetic powder of NiZn-based ferrite, MnZn-based ferrite, or the like may be used.

The substrate 70 is laminated on the first magnetic layer 11. The substrate 70 has a flat plate-like shape and is a portion that serves as a base in the process of manufacturing the inductor component 1. For example, the substrate 70 is formed of a sintered compact of a magnetic substrate made of ferrite, such as NiZn-based ferrite or MnZn-based ferrite, a non-magnetic substrate made of alumina or glass, or the like. The thickness of the substrate 70 is, for example, 300 μm or more and 1,000 μm or less (i.e., from 300 μm to 1,000 μm).

The inductor wiring line 100 is provided at the upper surface of the substrate 70 and extends in a direction parallel to the upper surface of the substrate 70. The inductor wiring line 100 is wound at the upper surface of the substrate 70 in a spiral shape around the axis of the inductor wiring line 100. The inductor wiring line 100 has a spiral shape having more than one turn. When viewed from above, the inductor wiring line 100 is wound in a spiral shape in a clockwise direction from the outer peripheral end thereof toward the inner peripheral end thereof. Note that the inductor wiring line 100 may be a curve having less than one turn or may partially have a straight line.

The thickness of the inductor wiring line 100 is, for example, 40 μm or more and 120 μm or less (i.e., from 40 μm to 120 μm). Specifically, the inductor wiring line 100 has a thickness of 45 μm and a line width of 50 and the distance between portions of the inductor wiring line 100 is 10 The distance between portions of the inductor wiring line 100 may be 3 μm or more and 20 μm or less (i.e., from 3 μm to 20 μm).

The inductor wiring line 100 includes a spiral portion 120, a first pad portion 111, and a second pad portion 112. The first pad portion 111 is connected to the first vertical wiring line 21, and the second pad portion 112 is connected to the second vertical wiring line 22. The spiral portion 120 extends from the first pad portion 111 and the second pad portion 112 in the direction parallel to the upper surface of the substrate 70 and is wound in a spiral shape while the first pad portion 111 and the second pad portion 112 respectively serve as the outer periphery end and the inner periphery end.

The first vertical wiring line 21 and the second vertical wiring line 22 extend from the inductor wiring line 100 in the direction in which the central axis AX extends and extend through the element body 10. The first vertical wiring line 21 extends upward from the upper surface of the first pad portion 111 of the inductor wiring line 100 and includes the first via wiring line 212 and a first columnar wiring line 211. The first via wiring line 212 extends though one of interlayer insulating layers 31, and the first columnar wiring line 211 extends upward from the first via wiring line 212 and extends through the second magnetic layer 12. The second vertical wiring line 22 extends upward from the upper surface of the second pad portion 112 of the inductor wiring line 100 and includes a second via wiring line 222 and a second columnar wiring line 221. The second via wiring line 222 extends through the other of the interlayer insulating layers 31, and the second columnar wiring line 221 extends upward from the second via wiring line 222 and extends through the second magnetic layer 12.

The inductor wiring line 100 corresponds to an example of a “first internal wiring line” described in the claims. The first columnar wiring line 211 corresponds to an example of a “second internal wiring line” described in the claims.

The inductor wiring line 100 is made of an electrically conductive material that is, for example, a metal material having low electric resistance, such as Cu, AG, Au, Fe, or an alloy including any of these. As a result, the direct-current resistance of the inductor component 1 can be reduced. The first vertical wiring line 21 and the second vertical wiring line 22 are each made of an electrically conductive material similar to that of the inductor wiring line 100.

The insulating layer 30 covers at least a portion of the inductor wiring line 100. The insulating layer 30 includes the interlayer insulating layers 31, resin walls 32, and an insulating underlayer 33. The interlayer insulating layers 31 cover the upper surface of the inductor wiring line 100. The resin walls 32 cover the side surface of the inductor wiring line 100. The insulating underlayer 33 covers the lower surface of the inductor wiring line 100. More specifically, the resin walls 32 are located on the same plane as the inductor wiring line 100 and provided between the turns of the inductor wiring line 100 and on the radially outer side and the radially inner side of the inductor wiring line 100. The interlayer insulating layers 31 cover the upper surface of the inductor wiring line 100 and have vias that are arranged at positions corresponding to the first and second pad portions 111 and 112 of the inductor wiring line 100. The interlayer insulating layers 31 are provided so as to fill gaps between the upper ends of the adjacent resin walls 32. Although the insulating layer 30 are formed of the two interlayer insulating layers 31, the resin walls 32, and the insulating underlayer 33, the insulating layer 30 may be formed of a single insulating layer, two insulating layers, or four or more insulating layers.

The interlayer insulating layers 31, the resin walls 32, and the insulating underlayer 33 are each made of an insulating material that does not contain a magnetic material and include, for example, any of an epoxy-based resin, a polyimide-based resin, a phenol-based resin, and a vinyl ether-based resin. As a result, the electrical insulation reliability is improved. The insulating underlayer 33 may contain a non-magnetic filler such as silica. The thickness of the insulating underlayer 33 is, for example, 10 μm or less.

The first external terminal 51 is disposed on the upper surface of the second magnetic layer 12 and covers an end surface of the first columnar wiring line 211 that is exposed at the upper surface. As a result, the first external terminal 51 is electrically connected to the first pad portion 111 of the inductor wiring line 100. The second external terminal 52 is disposed on the upper surface of the second magnetic layer 12 and covers an end surface of the second columnar wiring line 221 that is exposed at the upper surface. As a result, the second external terminal 52 is electrically connected to the second pad portion 112 of the inductor wiring line 100.

The first external terminal 51 and the second external terminal 52 are each made of an electrically conductive material. The first external terminal 51 and the second external terminal 52 each have, for example, a three-layered structure in which a Cu layer having low electric resistance and high stress resistance, a Ni layer having high corrosion resistance, and an Au layer having high wettability and high reliability are laminated together in this order from the inner side to the outer side.

FIG. 3A is an enlarged view of a portion A illustrated in FIG. 2. FIG. 3A illustrates a portion of the first section including the central axis AX. One of the interlayer insulating layer 31 has a first main surface 31X on the first pad portion 111 side, a second main surface 31Y on the first columnar wiring line 211 side, and a via 31Z extending between the first main surface 31X and the second main surface 31Y. The first main surface 31X includes a first portion 31Xa that is in contact with the first pad portion 111. The first main surface 31X further includes a third portion 31Xb that is not in contact with the first pad portion 111. The third portion 31Xb is located at an end portion of the first main surface 31X, the end portion being located on the via 31Z side. The second main surface 31Y includes a second portion 31Ya that is parallel to the first main surface 31X.

The interlayer insulating layer 31 includes a protrusion 312 that is in contact with the first columnar wiring line 211. When a straight line including the first portion 31Xa and a straight line including the second portion 31Ya are respectively defined as a first reference line S1 and a second reference line S2, the protrusion 312 is in contact with the first columnar wiring line 211 and is located between the second reference line S2 of the interlayer insulating layer 31 and the first columnar wiring line 211. In FIG. 3A, the first reference line S1 and the second reference line S2 are each indicated by a dotted line.

The protrusion 312 is located on the first columnar wiring line 211 side by entering the first columnar wiring line 211. This increases the degree of close contact between the interlayer insulating layer 31 and the first columnar wiring line 211, and as a result, the shear strength between the first columnar wiring line 211 and the first via wiring line 212 is improved. In particular, even when an external force acts in the width direction, the interlayer insulating layer 31 and the first columnar wiring line 211 are prevented from being separated from each other. Therefore, the connection reliability of the inductor component 1 is improved.

By providing the protrusion 312 of the interlayer insulating layer 31 on the first columnar wiring line 211 side, the shear strength between the first columnar wiring line 211 and the first via wiring line 212 can be further improved compared with the case of designing an ingenious shape of the via 31Z. In addition, by providing the protrusion 312 of the interlayer insulating layer 31 on the first columnar wiring line 211 side, the shear strength between the first columnar wiring line 211 and the first via wiring line 212 can be further improved compared with the case where the interlayer insulating layer 31 has a recess formed on the second main surface 31Y side. Furthermore, in the case where a recess is formed in the interlayer insulating layer 31 in such a manner as to be located on the second main surface 31Y side by, for example, grinding the interlayer insulating layer 31, the likelihood of residue generation also increases.

The interlayer insulating layer 31 includes the protrusion 312, which is located between the second reference line S2 and the first columnar wiring line 211, and a main body portion 311 that is located between the second reference line S2 and the first pad portion 111. The protrusion 312 and the main body portion 311 are integrally formed. In this case, it is not necessary to perform a separate process of forming the protrusion 312, the manufacturing cost is reduced.

The phrase “the protrusion 312 and the main body portion 311 are integrally formed” refers to a state in which the protrusion 312 and the main body portion 311 are formed so as to be in contact with each other without a clear interface therebetween.

The via 31Z has a first open end 31Za on the first pad portion 111 side and a second open end 31Zb on the first columnar wiring line 211 side. The via 31Z has an inner surface that connects the first open end 31Za and the second open end 31Zb to each other.

The protrusion 312 includes the second open end 31Zb of the via 31Z and forms a portion of the inner surface of the via 31Z. As a result, the degree of close contact between the interlayer insulating layer 31 and the first columnar wiring line 211 is further increased, and the shear strength between the first columnar wiring line 211 and the first via wiring line 212 is further improved.

The inner surface of the via 31Z is inclined such that the width of the via 31Z in a direction that is perpendicular to the central axis AX (the X direction in the XZ section) increases in a direction from the first pad portion 111 toward the first columnar wiring line 211. Only a portion of the inner surface of the via 31Z may be inclined in the manner described above.

FIG. 3B illustrates the periphery of the protrusion 312 in an enlarged manner. FIG. 3B is an enlarged view of a portion B illustrated in FIG. 3A.

A maximum height H₁ of the protrusion 312 in the direction in which the central axis AX extends may be 5% or more and 30% or less (i.e., from 5% to 30%) of a distance H₀ between the first reference line S1 and the second reference line S2 in the direction in which the central axis AX extends (hereinafter referred to as a “thickness H₀ of the interlayer insulating layer 31”). When the maximum height H₁ is 5% or more of the thickness H₀ of the interlayer insulating layer 31, an effect of improving the shear strength may easily be obtained by the protrusion 312. When the maximum height H₁ is 30% or less of the thickness H₀ of the interlayer insulating layer 31, the shape of the first columnar wiring line 211 is less likely to be affected. The maximum height H₁ of the protrusion 312 may be 10% or more of the thickness H₀ of the interlayer insulating layer 31 and may be 15% or more of the thickness H₀ of the interlayer insulating layer 31. The maximum height H₁ of the protrusion 312 may be 28% or less of the thickness H₀ of the interlayer insulating layer 31 and may be 25% or less of the thickness H₀ of the interlayer insulating layer 31. The maximum height H₁ of the protrusion 312 is the distance from the second reference line S2 to the highest point of the projection 312.

A maximum width W₁ of the protrusion 312 in the direction perpendicular to the central axis AX may be 1% or more and 80% or less (i.e., from 1% to 80%) of the thickness H₀ of the interlayer insulating layer 31. When the maximum width W₁ is 1% or more of the thickness H₀ of the interlayer insulating layer 31, the effect of improving the shear strength may easily be obtained by the protrusion 312. When the maximum width W₁ is 80% or less of the thickness H₀ of the interlayer insulating layer 31, the shape of the first columnar wiring line 211 is less likely to be affected. The maximum width W₁ of the protrusion 312 may be 5% or more of the thickness H₀ of the interlayer insulating layer 31 and may be 10% or more of the thickness H₀ of the interlayer insulating layer 31. The maximum width W₁ of the protrusion 312 may be 50% or less of the thickness H₀ of the interlayer insulating layer 31 and may be 40% or less of the thickness H₀ of the interlayer insulating layer 31. The maximum width W₁ of the protrusion 312 refers to the maximum width among the widths of the protrusions 312 in a direction parallel to the second reference line S2. The maximum width W₁ of the protrusion 312 is typically the width of the projection 312 at the second reference line S2.

(Wedge Portion)

As illustrated in FIG. 3A, the first via wiring line 212 includes a wedge portion 212a that is sandwiched between the interlayer insulating layer 31 and the first pad portion 111 in a direction parallel to the central axis AX. More specifically, the wedge portion 212a is disposed between the third portion 31Xb of the first main surface 31X, which is not in contact with the first pad portion 111, and the first pad portion 111. As a result, the wedge portion 212a exerts an anchor effect with respect to the interlayer insulating layer 31 and the first pad portion 111, and the degree of close contact between the first via wiring line 212 and the first pad portion 111 is also improved. Therefore, the connection reliability is further improved.

FIG. 3C illustrates the periphery of the wedge portion 212a in an enlarged manner. FIG. 3C is an enlarged view of a portion C illustrated in FIG. 3A. When a straight line that includes the first open end 31Za of the via 31Z and that is parallel to the central axis AX is defined as a third reference line S3, the wedge portion 212a is positioned such that the third reference line S3 of the first via wiring line 212 is located between the wedge portion 212a and the central axis AX. In FIG. 3C, the third reference line S3 is indicated by a dotted line.

The third portion 31Xb is inclined with respect to the first reference line S1 such that the distance between the third portion 31Xb and the first reference line S1 in the direction parallel to the central axis AX increases with decreasing distance from the central axis AX. As a result, when the first via wiring line 212 is formed by a plating method, a plating solution is likely to enter a space between the third portion 31Xb and the first pad portion 111, and thus, generation of a void in the wedge portion 212a is suppressed. A void may cause fracture of a plating coating film, that is, the first via wiring line 212 in this case. Only a portion of the third portion 31Xb may be inclined such that the distance between the third portion 31Xb and the first reference line S1 in the direction parallel to the central axis AX increases.

A height H2 of the wedge portion 212a may be 10% or more and 30% or less (i.e., from 10% to 30%) of the thickness H₀ of the interlayer insulating layer 31. When the height H₂ is 10% or more of the thickness H₀ of the interlayer insulating layer 31, the above-mentioned anchor effect may easily be obtained. When the height H₂ is 30% or less of the thickness H₀ of the interlayer insulating layer 31, the plating solution is likely to enter the space between the third portion 31Xb and the first pad portion 111 at the time of forming the first via wiring line 212 by a plating method, and thus, generation of a void in the wedge portion 212a may easily be suppressed. In addition, a circulation failure of the plating solution may be suppressed, and a plating coating film having high crystallinity may easily be formed. The height H₂ of the wedge portion 212a may be 15% or more of the thickness H₀ of the interlayer insulating layer 31 and may be 20% or more of the thickness H₀ of the interlayer insulating layer 31. The height H₂ of the wedge portion 212a may be 30% or less of the thickness H₀ of the interlayer insulating layer 31 and may be 25% or less of the thickness H₀ of the interlayer insulating layer 31. The height H2 of the wedge portion 212a is the distance from the first open end 31Za to a point of intersection of the third reference line S3 and the first pad portion 111.

(Recess, Projection)

As illustrated in FIG. 3A and FIG. 3C, the first pad portion 111 has a recess 111a that is recessed so as to be located below the first reference line S1. The first via wiring line 212 has a projection 212b that is fitted in the recess 111a. As a result, a contact area between the first pad portion 111 and the first via wiring line 212 is further increased, and thus, the degree of close contact is further improved.

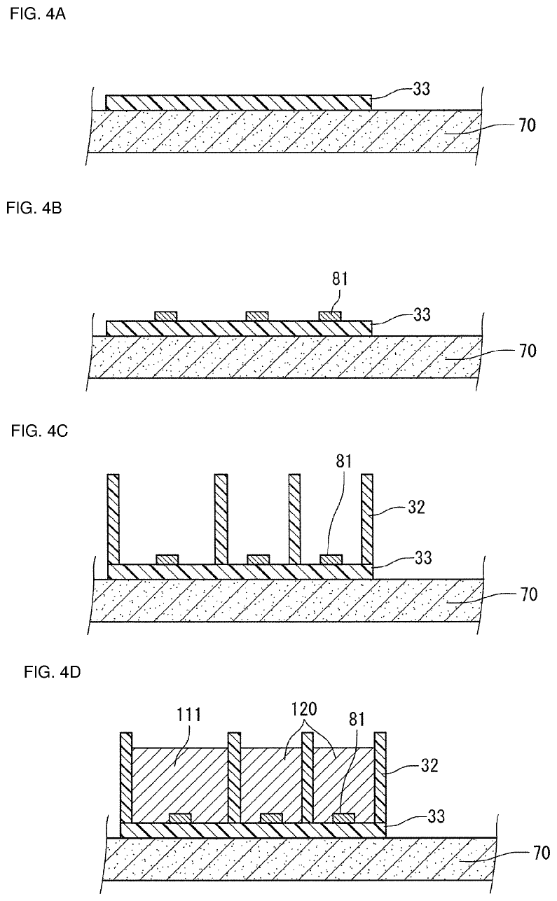

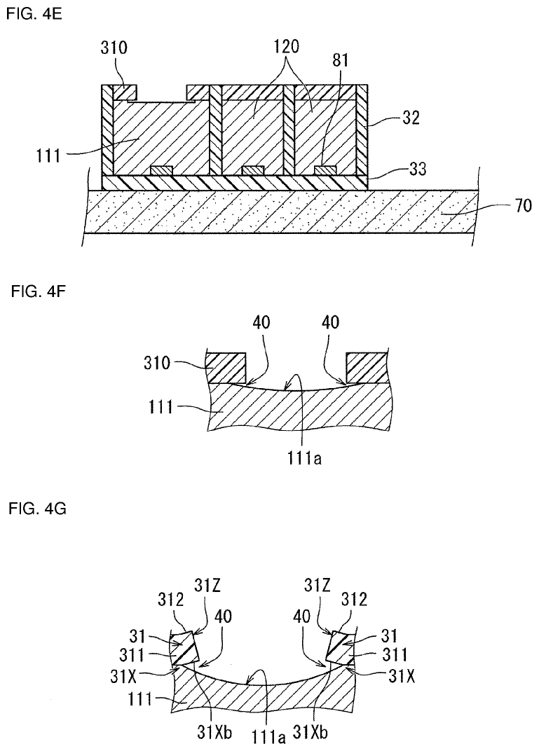

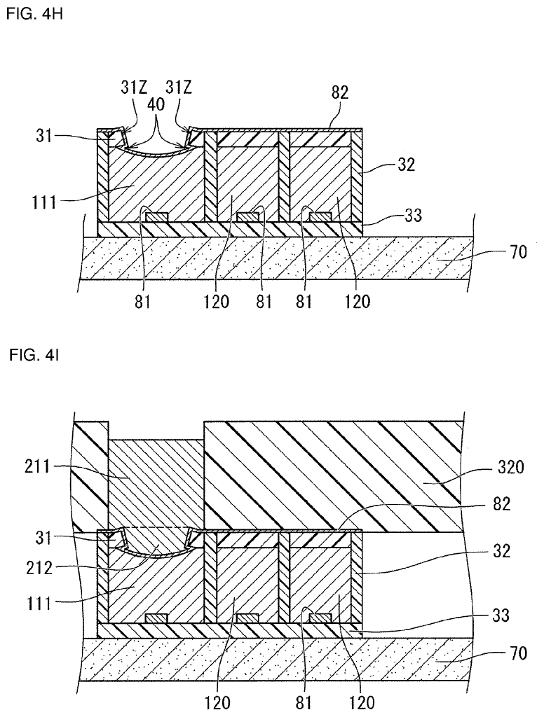

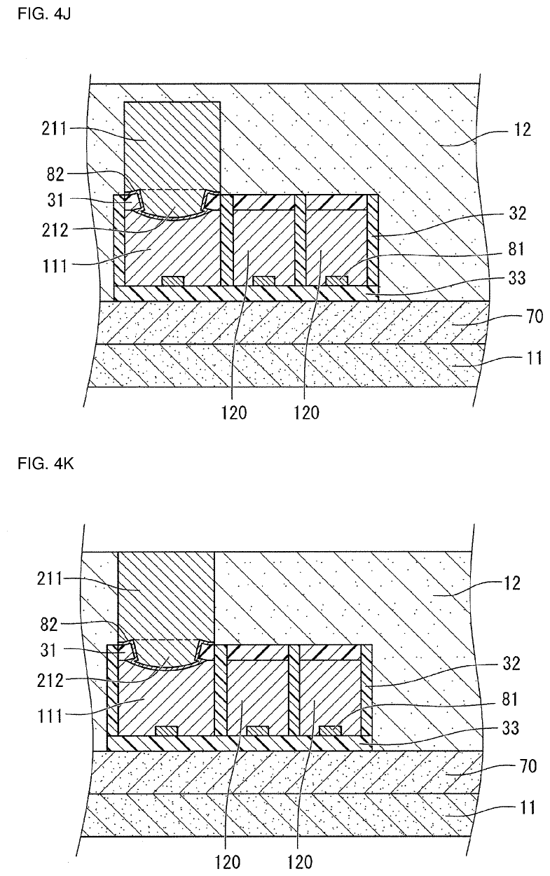

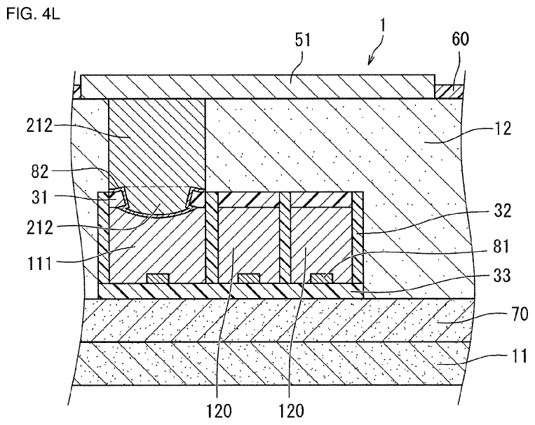

In the present embodiment, the protrusion 312 is formed as a result of the entire end portion of the interlayer insulating layer 31 on the via 31Z side being raised upward. In this case, the inclined third portion 31Xb is also formed, and a gap (a gap 40 illustrated in FIG. 4F and FIG. 4G) is formed between the interlayer insulating layer 31 and the first pad portion 111. In addition, the inner surface of the via 31Z has a shape tapered downward. A portion of the first via wiring line 212 enters the gap, so that the wedge portion 212a is formed. The phrase “the entire end portion of the interlayer insulating layer 31” refers to a region between the first main surface 31X and the second main surface 31Y at the end portion.

In FIG. 2, the section including the central axis AX includes the cross sections of the two via wiring lines 212 and 222. However, it is only necessary that at least one of the two via wiring lines, that is, the first via wiring line 212, have the above-described various structures, which are illustrated in FIG. 3A to FIG. 3C. In another section including the central axis AX, the above-described various structures in FIG. 3A to FIG. 3C may be fabricated or do not need to be fabricated. It is only necessary that at least one of the plurality of via wiring lines that are included in the inductor component 1 have the above-described various structures illustrated in FIG. 3A to FIG. 3C.

(Manufacturing Method)

A method of manufacturing the inductor component 1 will now be described with reference to FIG. 4A to FIG. 4L. FIG. 4A to FIG. 4L are diagrams corresponding to the first pad portion 111 and the first vertical wiring line 21, which are included in the inductor wiring line 100 and illustrated in FIG. 2.

As illustrated in FIG. 4A, the insulating underlayer 33 that does not contain a magnetic material is formed on the substrate 70. For example, the substrate 70 is made of sintered ferrite and has a flat plate-like shape.

The insulating underlayer 33 is made of, for example, a polyimide-based resin or an inorganic material that does not contain a magnetic material. The insulating underlayer 33 is formed by coating the substrate 70 with a polyimide-based resin by printing, application, or the like, and then performing patterning using a photolithography method in such a manner as to leave the polyimide-based resin in a region in which the inductor wiring line 100 is to be formed. An insulating film made of an inorganic material is formed on the substrate 70 by, for example, performing a dry process such as vapor deposition, sputtering, or chemical vapor deposition (CVD) on the substrate 70.

As illustrated in FIG. 4B, a seed layer 81 is formed on the insulating underlayer 33. More specifically, a material (e.g., a titanium/copper alloy) of the seed layer 81 is sputter-deposited onto the upper surface of the insulating underlayer 33, and patterning is performed by a subtractive method, so that the seed layer 81 is formed.

As illustrated in FIG. 4C, the resin walls 32 are formed on the insulating underlayer 33. For example, the resin walls 32 are made of a photosensitive permanent photoresist. The photosensitive permanent photoresist is a photoresist that is not removed after processing. More specifically, a material of the resin walls 32 is printed on the substrate 70 and exposed to light. After that, development is performed by using an organic solvent such as propylene glycol monomethyl ether acetate (PGMEA) and an alkaline developing solution such as tetramethylammonium hydroxide (TMAH). As a result, the material at portions that are not exposed to light is removed, and the resin walls 32 are formed.

As illustrated in FIG. 4D, the first pad portion 111 and the spiral portion 120 are formed on the seed layer 81. More specifically, plating is grown on the seed layer 81 by electrolytic plating. As a result, the first pad portion 111 and the spiral portion 120 are formed between the resin walls 32.

As illustrated in FIG. 4E, a photosensitive insulating layer 310 that covers the spiral portion 120 and has a through hole through which the upper surface of the first pad portion 111 is exposed is disposed. More specifically, a photosensitive insulating film is laminated so as to cover the first pad portion 111 and the spiral portion 120 from above. The photosensitive insulating film is also made of a photosensitive permanent photoresist. Then, the photosensitive insulating film is exposed to light so as to be photo-cured. After that, development is performed, so that the photosensitive insulating layer 310 having the through hole is formed, and a portion of the first pad portion 111 is exposed through the photosensitive insulating layer 310.

FIG. 4F is an enlarged view illustrating the periphery of the through hole formed in the photosensitive insulating layer 310. As illustrated in FIG. 4F, the recess 111a is formed in the portion of the first pad portion 111 that is exposed through the photosensitive insulating layer 310. The recess 111a is formed by performing an etching process. In this case, by performing etching isotropically, the recess 111a is formed, and in addition, the gap 40 is formed between the photosensitive insulating layer 310 and the first pad portion 111. The gap 40 causes the end portion of the photosensitive insulating layer 310 to be separated from the first pad portion 111. The separated portion of the photosensitive insulating layer 310, which is separated from the first pad portion 111, is raised upward upon being thermally-cured, so that the protrusion 312 is formed. The plating enters the gap 40, so that the wedge portion 212a is formed.

The maximum height H₁ and the maximum width W₁ of the protrusion 312 are controlled by the etching amount of the first pad portion 111. The etching amount is appropriately set in accordance with the size of the protrusion 312. For example, when the first pad portion 111 is formed by copper plating, a chemical agent that preferentially dissolves copper oxide rather than copper may be used for etching. Alternatively, the etching amount may be adjusted by appropriately adjusting the treatment time and temperature. The height H2 of the wedge portion 212a is also controlled by the etching amount of the first pad portion 111.

Similar to FIG. 4F, FIG. 4G is an enlarged view illustrating the periphery of the through hole, which is formed in the photosensitive insulating layer 310, in an enlarged manner. As illustrated in FIG. 4G, the interlayer insulating layer 31 that includes the protrusion 312 is formed. More specifically, the photosensitive insulating layer 310 is heated so as to be thermally-cured. In this case, because the outer surface side of the photosensitive insulating layer 310 is likely to shrink and the photosensitive insulating layer 310 includes the separated portion, the end portion of the photosensitive insulating layer 310 on the through hole side is raised upward in such a manner as to form the protrusion 312. According to this method, the main body portion 311 and the protrusion 312 are integrally formed, and thus, the manufacturing cost is reduced. The heating of the photosensitive insulating layer 310 is performed at, for example, a temperature of 150° C. or more and 200° C. or less (i.e., from 150° C. to 200° C.) for about one hour. The protrusion 312 forms the through hole, that is, a portion of the inner surface of the via 31Z. The separated portion of the photosensitive insulating layer 310 forms the third portion 31Xb that is included in the first main surface 31X of the interlayer insulating layer 31 and that is not in contact with the first pad portion 111.

As illustrated in FIG. 4H, a seed layer 82 is formed on the inner surface of the via 31Z, the exposed portion of the upper surface of the first pad portion 111, the upper surface of the interlayer insulating layer 31, and the upper surfaces of the resin walls 32 by sputtering. When the height of the gap 40 (the height H2 of the wedge portion 212a) is 10% or more and 30% or less (i.e., from 10% to 30%) of the thickness H₀ of the interlayer insulating layer 31, it becomes easier to form the seed layer also on the third portion 31Xb and the upper surface of the first pad portion 111, which form the gap 40. As a result, generation of a void in a plating coating film is suppressed in a subsequent plating step. A void may cause fracture of a plating coating film, that is, fracture of the first via wiring line 212 and the first columnar wiring line 211 in this case.

As illustrated in FIG. 4I, the first via wiring line 212 and the first columnar wiring line 211 are formed at a portion corresponding to the exposed portion of the upper surface of the first pad portion 111. More specifically, a resist film 320 is formed on the seed layer 82, and a cavity is formed at a position in the resist film 320, the position corresponding to the first via wiring line 212. Plating is grown on the seed layer 82 by performing electrolytic plating so as to form a plating layer in the above-mentioned cavity. As a result, the first via wiring line 212 and the first columnar wiring line 211 are formed in the cavity.

As illustrated in FIG. 4J, the resist film 320 is removed, and the exposed seed layer 82 is removed. Then, the second magnetic layer 12 is formed on the interlayer insulating layer 31. In addition, the first magnetic layer 11 is formed on the lower surface of the substrate 70. The first magnetic layer 11 and the second magnetic layer 12 are each formed by pressing a magnetic layer onto the interlayer insulating layer 31 or the lower surface of the substrate 70. Before the second magnetic layer 12 is pressed, a portion of the substrate 70 is ground so as to adjust the thickness. The substrate 70 may be removed.

As illustrated in FIG. 4K, the upper surface of the first columnar wiring line 211 is exposed by grinding the second magnetic layer 12.

As illustrated in FIG. 4L, the first external terminal 51 is formed on the upper surface of the first columnar wiring line 211, and a coating film 60 is formed in such a manner as to cover a portion of the second magnetic layer 12, the portion not being covered with the first external terminal 51. The coating film 60 is made of, for example, a solder resist. After that, dicing is performed by using a dicer or the like so as to manufacture the inductor component 1.

Note that the present disclosure is not limited to the above-described embodiment, and design changes can be made within the gist of the present disclosure.

In the above-described embodiment, although the inductor wiring line 100 has a single-layer structure, the plurality of inductor wiring lines 100 may be laminated in the direction in which the central axis AX extends. Alternatively, the plurality of inductor wiring lines 100 may be arranged in a direction perpendicular to the direction in which the central axis AX extends.

In the above-described embodiment, although the protrusion 312 and the main body portion 311 are integrally formed, the protrusion 312 and the main body portion 311 may be formed separately from each other. The protrusion 312 that is formed separately from the main body portion 311 may be disposed on the main body portion 311 on the first columnar wiring line 211 side.

In the above-described embodiment, although the protrusion 312 is provided at the second open end 31Zb of the via 31Z, the protrusion 312 may be provided at a position that is spaced apart from the second open end 31Zb of the via 31Z.

In the above-described embodiment, although the single protrusion 312 is provided at the second open end 31Zb of the via 31Z, the plurality of protrusions 312 may be provided.

In the above embodiment, although the first columnar wiring line 211 has been described as an example of the “second internal wiring line” described in the claims, the “second internal wiring line” described in the claims may be a second inductor wiring line.

In the above-described embodiment, although the first via wiring line 212 includes both the wedge portion 212a and the projection 212b, the first via wiring line 212 may include neither the wedge portion 212a nor the projection 212b or may include any one of them.

In the above-described embodiment, although the first pad portion 111 has the recess 111a, the first pad portion 111 does not necessarily have the recess 111a.

In the above-described embodiment, although the first main surface 31X of the interlayer insulating layer 31 includes the third portion 31Xb that is located at the end portion on the via 31Z side and that is not in contact with the first pad portion 111, the first main surface 31X of the interlayer insulating layer 31 does not necessarily include the third portion 31Xb.

In the above-described embodiment, although the entire third portion 31Xb of the interlayer insulating layer 31 is inclined such that the distance between the third portion 31Xb and the first reference line S1 increases with decreasing distance from the central axis AX, a portion of the third portion 31Xb may be inclined, that is, the third portion 31Xb may include an inclined portion. The third portion 31Xb does not necessarily include an inclined portion.

In the above-described embodiment, although the inner surface of the via 31Z is inclined such that the width of the via 31Z increases in a direction from the first pad portion 111 toward the first columnar wiring line 211, a portion of the inner surface of the via 31Z may be inclined, that is, the inner surface of the via 31Z may include an inclined portion. The inner surface of the via 31Z may include an inclined portion such that the width of the via 31Z decreases in a direction from the first pad portion 111 toward the first columnar wiring line 211. The inner surface of the via 31Z may extend in a direction along the central axis AX.

The present disclosure includes the following aspects.

<1> An inductor component comprising a first internal wiring line; a second internal wiring line; an interlayer insulating layer that is disposed between the first internal wiring line and the second internal wiring line and that has a first main surface facing the first internal wiring line, a second main surface facing the second internal wiring line, and a via extending between the first main surface and the second main surface; and a via wiring line that is inserted through the via and that electrically connects the first internal wiring line and the second internal wiring line to each other. In a first section including a central axis of the via wiring line, the first main surface includes a first portion that is in contact with the first internal wiring line, the second main surface includes a second portion that is parallel to the first portion, a straight line that includes the first portion is defined as a first reference line, a straight line that includes the second portion is defined as a second reference line, and the interlayer insulating layer includes a protrusion that is in contact with the second internal wiring line and that is located between the second reference line and the second internal wiring line.

<2> The inductor component described in <1>, wherein, in the first section, the via has a first open end facing the first internal wiring line and a second open end facing the second internal wiring line, and the protrusion includes the second open end of the via and forms a portion of an inner surface of the via.

<3> The inductor component described in <1> or <2>, wherein a maximum height of the protrusion in a direction in which the central axis extends is 5% or more and 30% or less (i.e., from 5% to 30%) of a distance between the first reference line and the second reference line in the direction in which the central axis extends.

<4> The inductor component described in any one of <1> to <3>, wherein a maximum width of the protrusion in a direction perpendicular to the central axis is 1% or more and 80% or less (i.e., from 1% to 80%) of a distance between the first reference line and the second reference line in the direction in which the central axis extends.

<5> The inductor component described in any one of <1> to <4>, wherein the interlayer insulating layer includes the protrusion and a main body portion that is located between the second reference line and the first internal wiring line, and the protrusion and the main body portion are integrally formed.

<6> The inductor component described in any one of <1> to <5>, wherein, in the first section, the via wiring line includes a wedge portion that is sandwiched between the interlayer insulating layer and the first internal wiring line in a direction parallel to the central axis.

<7> The inductor component described in <6>, wherein the via has a first open end facing the first internal wiring line and a second open end facing the second internal wiring line, and a straight line that includes the first open end and that is parallel to the central axis is defined as a third reference line. Also the wedge portion is positioned such that the third reference line of the via wiring line is located between the wedge portion and the central axis. In addition, a height of the wedge portion between the first open end and a point of intersection of the third reference line and the first internal wiring line is 10% or more and 30% or less (i.e., from 10% to 30%) of a distance between the first reference line and the second reference line in the direction in which the central axis extends.

<8> The inductor component described in <6> or <7>, wherein, in the first section, the first main surface includes a third portion that is located at an end portion facing the via and that is not in contact with the first internal wiring line, and the wedge portion is positioned between the third portion and the first internal wiring line.

<9> The inductor component described in <8>, wherein, in the first section, the third portion includes an inclined portion such that a distance between the third portion and the first reference line in the direction parallel to the central axis increases with decreasing distance from the central axis.

<10> The inductor component described in any one of <1> to <9>, wherein, in the first section, an inner surface of the via includes an inclined portion such that a width of the via in a direction perpendicular to the central axis increases in a direction from the first internal wiring line toward the second internal wiring line.

<11> The inductor component described in any one of <1> to <10>, wherein the first internal wiring line has a recess that is recessed in such a manner as to be located below the first reference line, and wherein the via wiring line has a projection that is fitted in the recess.

<12> The inductor component described in any one of <1> to <11>, further comprising an element body that includes a magnetic layer. The first internal wiring line and the second internal wiring line are provided in the element body, and at least one of the first internal wiring line and the second internal wiring line is an inductor wiring line.

What is claimed is:

1. An inductor component comprising:
a first internal wiring line;
a second internal wiring line;
an interlayer insulating layer between the first internal wiring line and the second internal wiring line and that has a first main surface facing the first internal wiring line, a second main surface facing the second internal wiring line, and a via extending between the first main surface and the second main surface; and
a via wiring line extending through the via and electrically connecting the first internal wiring line and the second internal wiring line to each other,
wherein, in a first section including a central axis of the via wiring line, the first main surface includes a first portion that is in contact with the first internal wiring line,
the second main surface includes a second portion that is parallel to the first portion,
a straight line that includes the first portion is defined as a first reference line,
a straight line that includes the second portion is defined as a second reference line, and
the interlayer insulating layer includes a protrusion that is in contact with the second internal wiring line and that is between the second reference line and the second internal wiring line.

2. The inductor component according to claim 1, wherein
in the first section,
the via has a first open end facing the first internal wiring line and a second open end facing the second internal wiring line, and
the protrusion includes the second open end of the via and configures a portion of an inner surface of the via.

3. The inductor component according to claim 1, wherein
a maximum height of the protrusion in a direction in which the central axis extends is from 5% to 30% of a distance between the first reference line and the second reference line in the direction in which the central axis extends.

4. The inductor component according to claim 1, wherein
a maximum width of the protrusion in a direction perpendicular to the central axis is from 1% to 80% of a distance between the first reference line and the second reference line in a direction in which the central axis extends.

5. The inductor component according to claim 1, wherein
the interlayer insulating layer includes the protrusion and a main body portion that is between the second reference line and the first internal wiring line, and
wherein the protrusion and the main body portion are integral.

6. The inductor component according to claim 1, wherein
in the first section,
the via wiring line includes a wedge portion that is sandwiched between the interlayer insulating layer and the first internal wiring line in a direction parallel to the central axis.

7. The inductor component according to claim 6, wherein
the via has a first open end facing the first internal wiring line and a second open end facing the second internal wiring line,
a straight line that includes the first open end and that is parallel to the central axis is defined as a third reference line,
the wedge portion is positioned such that the third reference line of the via wiring line is located between the wedge portion and the central axis, and
a height of the wedge portion between the first open end and a point of intersection of the third reference line and the first internal wiring line is from 10% to 30% of a distance between the first reference line and the second reference line in a direction in which the central axis extends.

8. The inductor component according to claim 6, wherein
in the first section,
the first main surface includes a third portion that is at an end portion facing the via and that is not in contact with the first internal wiring line, and
the wedge portion is between the third portion and the first internal wiring line.

9. The inductor component according to claim 8, wherein
in the first section,
the third portion includes an inclined portion such that a distance between the third portion and the first reference line in the direction parallel to the central axis increases with decreasing distance from the central axis.

10. The inductor component according to claim 1, wherein
in the first section,
an inner surface of the via includes an inclined portion such that a width of the via in a direction perpendicular to the central axis increases in a direction from the first internal wiring line toward the second internal wiring line.

11. The inductor component according to claim 1, wherein
the first internal wiring line has a recess that is recessed below the first reference line, and
the via wiring line has a projection that is in the recess.

12. The inductor component according to claim 1, further comprising:
an element body that includes a magnetic layer,
wherein
the first internal wiring line and the second internal wiring line are in the element body, and
at least one of the first internal wiring line and the second internal wiring line is an inductor wiring line.

13. The inductor component according to claim 2, wherein
a maximum height of the protrusion in a direction in which the central axis extends is from 5% to 30% of a distance between the first reference line and the second reference line in the direction in which the central axis extends.

14. The inductor component according to claim 2, wherein
a maximum width of the protrusion in a direction perpendicular to the central axis is from 1% to 80% of a distance between the first reference line and the second reference line in a direction in which the central axis extends.

15. The inductor component according to claim 2, wherein
the interlayer insulating layer includes the protrusion and a main body portion that is between the second reference line and the first internal wiring line, and
wherein the protrusion and the main body portion are integral.

16. The inductor component according to claim 2, wherein
in the first section,
the via wiring line includes a wedge portion that is sandwiched between the interlayer insulating layer and the first internal wiring line in a direction parallel to the central axis.

17. The inductor component according to claim 16, wherein
the via has a first open end facing the first internal wiring line and a second open end facing the second internal wiring line,
a straight line that includes the first open end and that is parallel to the central axis is defined as a third reference line,
the wedge portion is positioned such that the third reference line of the via wiring line is located between the wedge portion and the central axis, and
a height of the wedge portion between the first open end and a point of intersection of the third reference line and the first internal wiring line is from 10% to 30% of a distance between the first reference line and the second reference line in a direction in which the central axis extends.

18. The inductor component according to claim 2, wherein
in the first section,
an inner surface of the via includes an inclined portion such that a width of the via in a direction perpendicular to the central axis increases in a direction from the first internal wiring line toward the second internal wiring line.

19. The inductor component according to claim 2, wherein
the first internal wiring line has a recess that is recessed below the first reference line, and
the via wiring line has a projection that is in the recess.

20. The inductor component according to claim 2, further comprising:
an element body that includes a magnetic layer,
wherein
the first internal wiring line and the second internal wiring line are in the element body, and
at least one of the first internal wiring line and the second internal wiring line is an inductor wiring line.
